(19) United States
(12) Patent Application Publication
(10) Pub. No.: US 2024/0321551 A1
(43) Pub. Date: Sep. 26, 2024

(54) SEMICONDUCTOR DEVICE MANUFACTURING METHOD AND FILM FORMING APPARATUS

(71) Applicant: SONY SEMICONDUCTOR SOLUTIONS CORPORATION, Kanagawa (JP)

(72) Inventors: Kiyotaka TABUCHI, Kumamoto (JP); Kazunori NAGAHATA, Kumamoto (JP); Yuji MIYATA, Kumamoto (JP); Yuya MIZOKAMI, Kumamoto (JP); Masaharu SHIRATANI, Fukuoka (JP); Kunihiro KAMATAKI, Fukuoka (JP)

(73) Assignee: SONY SEMICONDUCTOR SOLUTIONS CORPORATION, Kanagawa (JP)

(21) Appl. No.: 18/575,915

(22) PCT Filed: Feb. 14, 2022
(86) PCT No.: PCT/JP2022/005573

§ 371 Date: Jan. 2, 2024

(30) Foreign Application Priority Data
Jul. 9, 2021 (JP) 2021-114221

(51) Int. Cl. H01J 37/32; H01L 21/02

(52) U.S. Cl. CPC H01J 37/32128; H01J 37/32146; H01J 37/32155; H01L 21/02274; H01J 2237/3321; H01J 2237/3323

(57) ABSTRACT

Provided are a semiconductor device manufacturing method and a film forming apparatus that are capable of improving coverage in a film formation process while suppressing a decrease in productivity. The semiconductor device manufacturing method includes a film formation process of forming a film on a side toward one surface of a substrate disposed in a chamber by using a plasma CVD method. The film formation process changes plasma density in the chamber according to a preset waveform while forming the film.

### TECHNICAL FIELD

The present disclosure relates to a semiconductor device manufacturing method and a film forming apparatus.

### BACKGROUND ART

With recent miniaturization of devices, an aspect ratio of processed shapes is increasing, and uniform coating on high-aspect shapes is required. A coating insulating film has been formed by plasma CVD (Chemical Vapor Deposition), high density plasma (HDP) CVD (see, for example, PTL 1), or atomic layer deposition (ALD).

However, in a case where the aspect ratio of a shape to be embedded becomes high, plasma CVD requires a large film forming amount for an uneven frontage. This may result in insufficient coverage of an uneven sidewall. HDP CVD is bottom-up film formation, and unable to easily achieve conformal coating (i.e., coating along the unevenness of a base). Further, in a case where the aspect ratio becomes high, HDP CVD allows the frontage to close first, and is likely to cause poor embedding (i.e., the formation of voids). Meanwhile, ALD has excellent coverage. However, ALD has a low film formation rate, and thus has very poor productivity.

Another known method is to form a film on the unevenness by using HDP CVD, then widen the frontage of the unevenness by etching, and bury the unevenness again by using HDP CVD to improve embeddability (see, for example, PTL 2). Yet another known method is to combine plasma CVD and ALD for the purpose of providing higher productivity than in the case of forming a film by using ALD alone (see, for example, PTL 3). However, these methods still have low productivity because they require multiple film formation processes performed by using different methods, which neither allow an etching process to be performed in the middle of a CVD process nor allow film formation to be performed continuously in the same equipment.

### CITATION LIST

### Patent Literature

PTL 1: Japanese Patent Laid-open No. 2005-302848
PTL 2: Japanese Patent Laid-open No. 2003-031649
PTL 3: Japanese Patent Laid-open No. 2010-283145

### SUMMARY

### Technical Problem

A film forming technology capable of improving coverage while suppressing a decrease in productivity is desired.

The present disclosure has been made in view of the above circumstances, and an object thereof is to provide a semiconductor device manufacturing method and a film forming apparatus that are capable of improving coverage in a film formation process while suppressing a decrease in productivity.

### Solution to Problem

A semiconductor device manufacturing method according to an aspect of the present disclosure includes a film formation process of forming a film on a side toward one surface of a substrate disposed in a chamber by using a plasma CVD method. In the film formation process, plasma density in the chamber changes according to a preset waveform while the film is formed.

Accordingly, the plasma density in the chamber can repeatedly alternate between a low-density state and a high-density state. Ion angular distribution with respect to the one surface of the substrate changes during film formation. The ion angular distribution narrows in the high-density state, and widens in the low-density state. As a result, even if the one surface of the substrate is uneven, ions can easily reach the side surface or bottom surface of unevenness. This makes it possible to improve coverage.

Further, film formation using plasma whose density changes according to a preset waveform (i.e., density-modulated plasma) allows a plasma atmosphere to remain uninterrupted during film formation. Therefore, the time required for film formation is equivalent to that in a case where a film is formed by plasma CVD. Consequently, in the film formation process, it is possible to improve coverage while suppressing a decrease in productivity.

A film forming apparatus according to an aspect of the present disclosure changes the plasma density in the chamber according to a preset waveform while forming a film on a substrate disposed in a chamber by using the plasma CVD method. Consequently, since the film is formed by using density-modulated plasma, it is possible to improve coverage while suppressing a decrease in productivity.

### BRIEF DESCRIPTION OF DRAWINGS

FIG. 1 is a cross-sectional view schematically illustrating a film formation process based on plasma CVD according to a first embodiment of the present disclosure.

FIG. 2 is a graph illustrating a waveform of density-modulated plasma according to the first embodiment of the present disclosure.

FIG. 3 is a graph illustrating a relation between the voltage amplitude of input power and the generation of high- and low-density states of the density-modulated plasma according to the first embodiment of the present disclosure.

FIG. 4A is a set of diagrams schematically illustrating plasma potential and horizontal potential acting on ions and an ion angular distribution in the high-density state of the density-modulated plasma depicted in FIG. 2.

FIG. 4B is a set of diagrams schematically illustrating plasma potential and horizontal potential acting on ions and an ion angular distribution in the low-density state of the density-modulated plasma depicted in FIG. 2.

FIG. 4C is a cross-sectional view schematically illustrating the incident angle distribution of ions incident on the side surface of a trench that are depicted in FIGS. 4A and 4B.

FIG. 5 is a cross-sectional view illustrating a film that is formed by plasma CVD according to the first embodiment of the present disclosure.

FIG. 6 is a schematic diagram illustrating an example configuration of a film forming apparatus according to the first embodiment of the present disclosure.

FIG. 7 is a graph illustrating a waveform of the density-modulated plasma according to a second embodiment of the present disclosure.

FIG. 8 is a graph illustrating the relation between the voltage amplitude of input power and the generation of high- and low-density states of the density-modulated plasma according to the second embodiment of the present disclosure.

FIG. 9A is a set of diagrams schematically illustrating plasma potential and horizontal potential acting on ions and an ion angular distribution in a first change state and a second change state of the density-modulated plasma depicted in FIG. 7.

FIG. 9B is a diagram schematically illustrating plasma potential and horizontal potential acting on ions and an ion angular distribution in the low-density state, the first change state, the high-density state, and the second change state of the density-modulated plasma depicted in FIG. 7.

FIG. 9C is a cross-sectional view schematically illustrating the incident angle distribution of ions incident on the side surface of a trench that are depicted in FIGS. 9A and 9B.

FIG. 10 is a graph illustrating a waveform of the density-modulated plasma according to an example of the second embodiment of the present disclosure.

FIG. 11A is a graph illustrating a waveform of plasma according to a comparative example of the present disclosure.

FIG. 11B is a diagram schematically illustrating plasma potential and horizontal potential acting on ions and an ion angular distribution in the comparative example depicted in FIG. 11A.

FIG. 11C is a cross-sectional view schematically illustrating the incident angle distribution of ions incident on the side surface of a trench that is depicted in FIG. 11B.

FIG. 12 is a cross-sectional view illustrating evaluation parts of a film.

FIG. 13 is a graph illustrating the results of evaluation of coverage in an example of the second embodiment and in a comparative example.

FIG. 14 is a graph illustrating the results of evaluation of film quality in the example of the second embodiment and in the comparative example.

FIG. 15 is a diagram illustrating specific examples 1 to 3 of the density-modulated plasma according to the embodiments of the present disclosure.

FIG. 16 is a diagram illustrating specific examples 4 to 6 of the density-modulated plasma according to the embodiments of the present disclosure.

FIG. 17 is a diagram illustrating specific examples 7 to 9 of the density-modulated plasma according to the embodiments of the present disclosure.

FIG. 18 is a diagram illustrating specific examples 10 and 11 of the density-modulated plasma according to the embodiments of the present disclosure.

### DESCRIPTION OF EMBODIMENTS

Embodiments of the present disclosure will now be described with reference to the accompanying drawings. In the drawings referred to in the subsequent description, portions identical or similar to each other are designated by identical or similar reference signs. However, since the drawings are schematic, it should be noted that, for example, a relation between thicknesses and planar dimensions and the thickness ratio between individual layers are different from those in practice. Therefore, specific thicknesses and dimensions should be determined in consideration of the subsequent description. Further, it is obvious that the drawings include portions with different dimensional relations and ratios.

Definitions of upward, downward, and other directions mentioned in the subsequent description are merely formulated for convenience of explanation, and not intended to limit the technological idea of the present disclosure. It is obvious that, for example, in a case where a target rotated 90 degrees is observed, an up-down direction is read as a left-right direction, and in a case where a target rotated 180 degrees is observed, the up-down direction is read as a reversed up-down direction.

### First Embodiment

### (Film Formation Process)

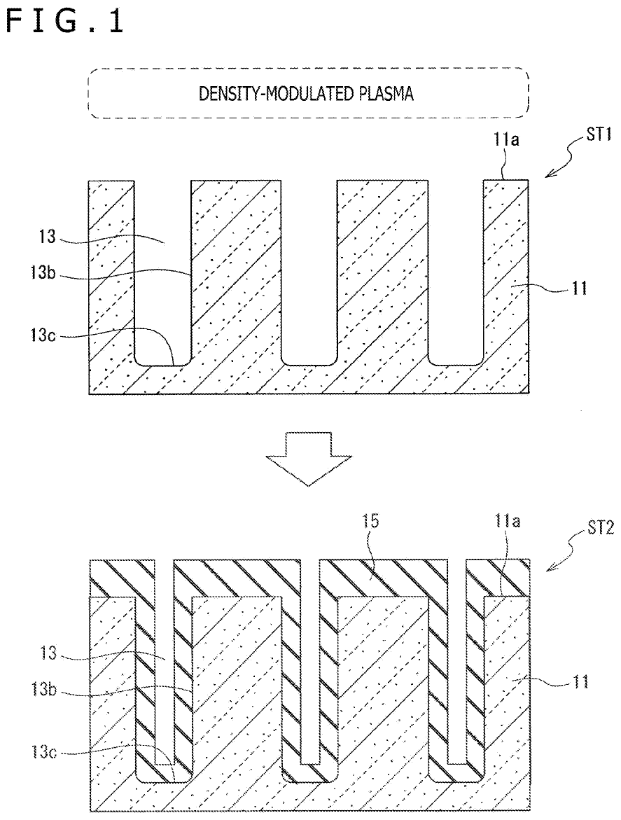

FIG. 1 is a cross-sectional view schematically illustrating a film formation process based on plasma CVD according to a first embodiment of the present disclosure. In the film formation process in the present disclosure, as depicted in FIG. 1, a substrate 11 is disposed in a chamber 51 that can be depressurized (see later-described FIG. 6), and the chamber 51 is depressurized to generate plasma (step ST1). Subsequently, atoms and molecules of a source gas are excited into reaction in a plasma atmosphere, and then ionized atoms and molecules (hereinafter referred to also as ions) are allowed to reach the side toward a surface 11a of the substrate 11 (an example of “one surface” in the present disclosure) in order to form a film 15 on the side toward the surface 11a (step ST2).

As depicted in FIG. 1, in a case where a trench 13 (an example of “unevenness” in the present disclosure) is provided on the side toward the surface 11a of the substrate 11, the film 15 is formed on the frontage of the trench 13 (i.e., the opening end face and its vicinity) and on a side surface 13b and a bottom surface 13c of the trench 13.

In the film formation process according to the first embodiment of the present disclosure, plasma density in the chamber 51 changes according to a preset waveform while the film 15 is being formed. In this document, the plasma whose density changes according to the preset waveform is referred to as the “density-modulated plasma.”

### (Density-Modulated Plasma)

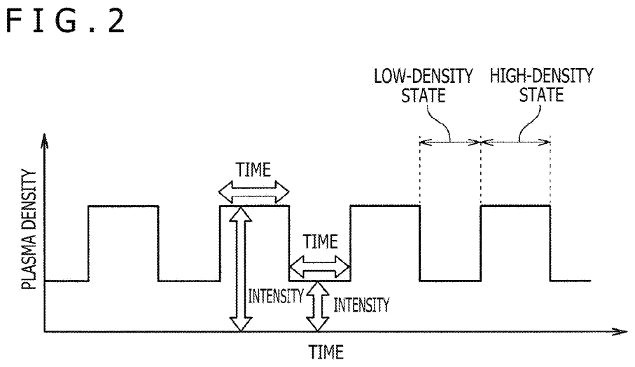

FIG. 2 is a graph illustrating a waveform of the density-modulated plasma according to the first embodiment of the present disclosure. In FIG. 2, a vertical axis represents the plasma density in the chamber 51 (see later-described FIG. 6), and the horizontal axis represents time. As depicted in FIG. 2, the waveform of the density-modulated plasma repeatedly alternates between a low-density state and a high-density state. The plasma density is low in the low-density state and high in the high-density state. The frequency of the waveform of the density-modulated plasma depicted in FIG. 2 is in the range, for example, of 0.1 Hz to 2 MHz. The density-modulated plasma can be generated, for example, by modulating the intensity of input power supplied to an anode electrode 52 (see later-described FIG. 6; an example of a “first electrode” in the present disclosure) that is disposed in the chamber 51 for plasma generation.

### (Input Power)

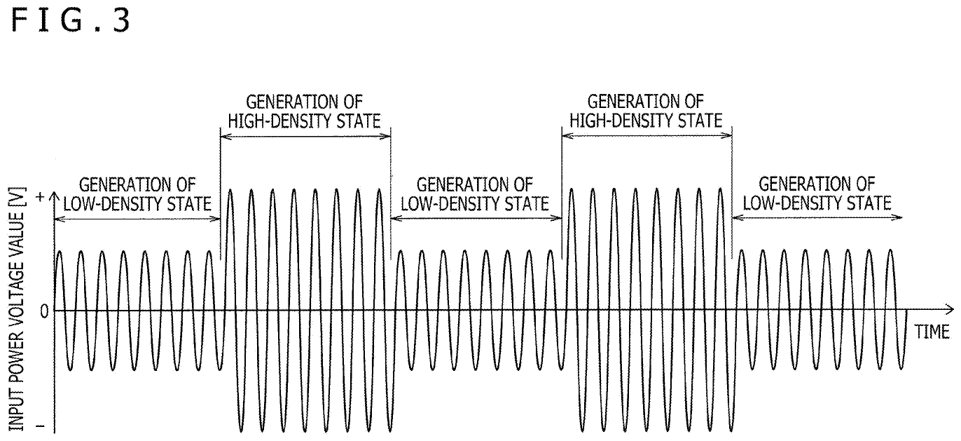

FIG. 3 is a graph illustrating a relation between the voltage amplitude of input power and the generation of high- and low-density states of the density-modulated plasma according to the first embodiment of the present disclosure. In FIG. 3, the vertical axis represents the voltage value of the input power, and the horizontal axis represents time. Regarding FIG. 3, it should be noted that the frequency of the input power is constant, for example, at 13.56 MHz. In this document, the frequency of the input power may be referred to as the frequency of a high-frequency power supply or the power-supply frequency. Further, the voltage of the input power may be referred to as the voltage of a high-frequency power supply or the power-supply voltage.

In a case where the frequency of the input power is constant, the intensity of power to be applied to the anode electrode 52 can be decreased by decreasing the amplitude of the voltage of the input power, and thus the plasma density in the chamber 51 can be placed in the low-density state. Further, the intensity of power to be applied to the anode electrode 52 can be increased by increasing the voltage amplitude of the input power, and thus the plasma density in the chamber 51 can be placed in the high-density state. The intensity of the input power can be modulated by causing the input power to repeatedly alternate at regular intervals between a state where the voltage amplitude is small and a state where the voltage amplitude is large (i.e., by modulating the voltage amplitude of the input power). As depicted in FIG. 2, it is possible to generate the density-modulated plasma with a waveform that repeatedly alternates between the low-density state and the high-density state.

By controlling the intensity of the input power and the time for maintaining the intensity of the input power, the intensity of plasma potential in each of the low- and high-density states (e.g., equivalent to the level of plasma density in FIG. 2) and the time during which each state continues can be adjusted to desired values.

### (Ion Angular Distribution)

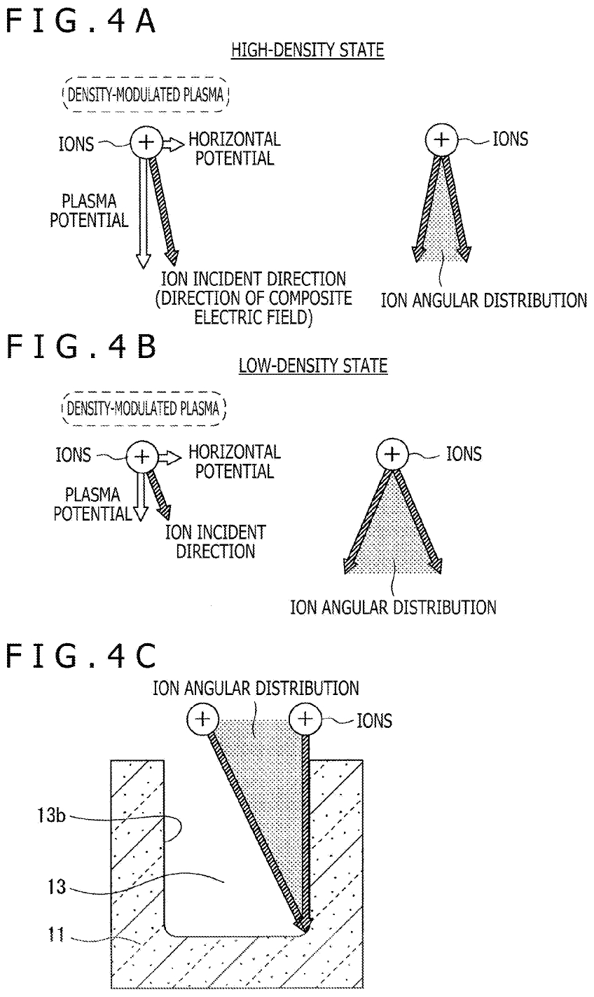

FIG. 4A is a set of diagram schematically illustrating the plasma potential and horizontal potential acting on ions and the angular distribution of ion incident direction (hereinafter referred to also as the ion angular distribution) in the high-density state of the density-modulated plasma depicted in FIG. 2. FIG. 4B is a set of diagram schematically illustrating the plasma potential and horizontal potential acting on ions and the ion angular distribution in the low-density state of the density-modulated plasma depicted in FIG. 2. In each of FIGS. 4A and 4B, the left diagram depicts the plasma potential and the horizontal potential, and the right diagram depicts the ion angular distribution. FIG. 4C is a cross-sectional view schematically illustrating the incident angle distribution of ions incident on the side surface 13b of the trench 13 that are depicted in FIGS. 4A and 4B. It should be noted that the ions are particles, namely atoms and molecules, of the source gas that are positively charged by electron emission. The plasma potential is the potential of plasma that is excited between the anode electrode 52 and a cathode electrode 53 when power is applied to the anode electrode 52 and the cathode electrode 53 (see later-described FIG. 6; an example of a “second electrode” in the present disclosure) in the chamber 51, and is a potential in the vertical direction. The horizontal potential is a potential in the horizontal direction.

As depicted in FIGS. 4A and 4B, the plasma potential acting on the ions changes in magnitude with the plasma density, and is high in the high-density state and low in the low-density state. Further, studies conducted by the inventors of the present disclosure have revealed that the horizontal potential is generated when the plasma density changes from the low-density state to the high-density state (or from the high-density state to the low-density state). The conducted studies have also revealed that the larger the amount of change in plasma density per unit time (that is, the slope of the change), the higher the generated horizontal potential.

In the waveform of the density-modulated plasma depicted in FIG. 2, the slope of the change from the low-density state to the high-density state and the slope of the change from the high-density state to the low-density state have opposite signs and the same absolute value of magnitude. Therefore, the horizontal electric field generated when the plasma density changes from the low-density state to the high-density state and the horizontal electric field generated when the plasma density changes from the high-density state to the low-density state have opposite directions and the same absolute value of magnitude. It should be noted that, even when the plasma density remains unchanged, some horizontal potential is generated due, for instance, to a diffusion potential.

In the waveform of the density-modulated plasma depicted in FIG. 2, the change from the low-density state to the high-density state and the change from the high-density state to the low-density state occur within a very short period of time. The slope of the change in plasma density is large (e.g., close to 90°), and a high horizontal potential is instantaneously generated, but the period during which the horizontal potential is generated is short. Therefore, in the waveform of the density-modulated plasma depicted in FIG. 2, the horizontal potential during film formation can be considered to be substantially constant.

The potentials acting on the ions are the plasma potential and the horizontal potential. That is, a composite electric field, namely, a combination of a vertical electric field and a horizontal electric field, acts on the ions. The plasma potential is lower in the low-density state than in the high-density state. Therefore, as depicted in FIGS. 4A and 4B, the slope of the composite electric field in the horizontal direction is higher in the low-density state than in the high-density state, and the ion angular distribution due to the composite electric field becomes wider. In FIG. 4C, the angle of incidence of ions on the side surface 13b of the trench 13 is larger in the low-density state than in the high-density state.

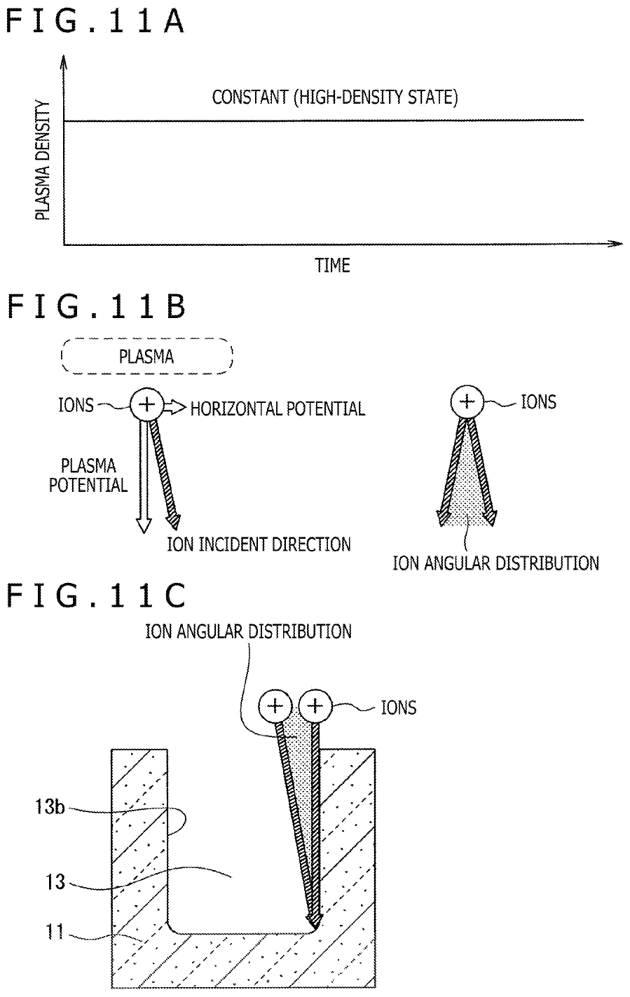

In plasma CVD using the density-modulated plasma depicted in FIG. 2, film formation in the high-density state (i.e., film formation at high power intensity) and film formation in the low-density state (i.e., film formation at low power intensity) are repeated. Therefore, the ion angular distribution changes and becomes wider in the low-density state than in the case of film formation by ordinary plasma CVD (e.g., a comparative example depicted in later-described FIGS. 11A to 11C). Consequently, compared with the later-described comparative example, a larger number of ions can be incident on the side surface 13b of the trench 13. This makes it easier to form a film on the side surface 13b, and thus improves coverage.

Further, the size of nanoparticles generated in the gas phase within the chamber tends to become smaller as the plasma density decreases. The smaller the size of the nanoparticles, the higher the density of the film formed by aggregation of the nanoparticles tends to be. In plasma CVD using the density-modulated plasma depicted in FIG. 2, the plasma density decreases at regular intervals. Therefore, the density of the film in the trench can be made higher than in the later-described comparative example in which a film is formed by ordinary plasma CVD. This makes it possible to improve film quality.

### (Coverage, Etc.)

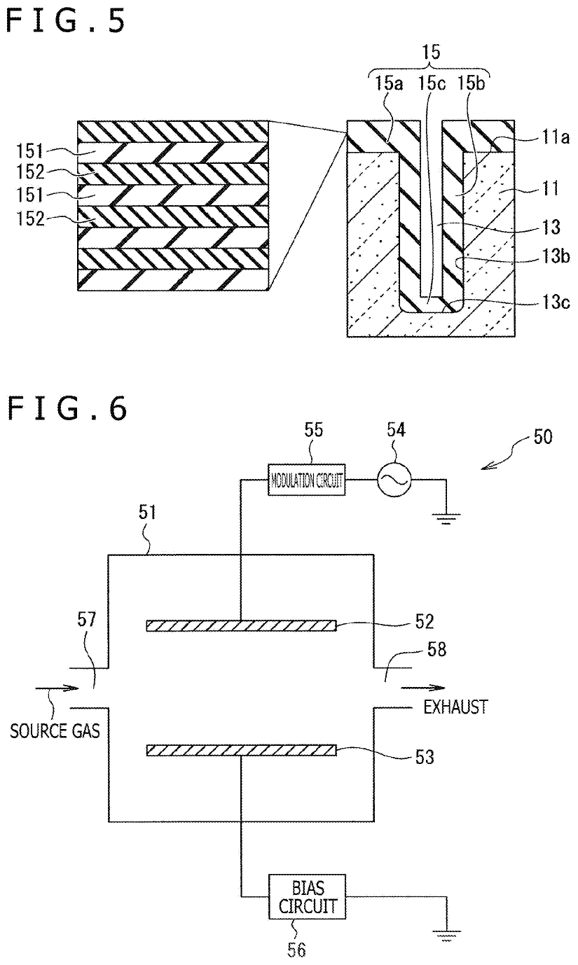

FIG. 5 is a cross-sectional view illustrating a film that is formed by plasma CVD according to the first embodiment of the present disclosure. In plasma CVD according to the first embodiment of the present disclosure, the density-modulated plasma is used, so that the ion angular distribution changes between the low-density state and the high-density state to provide a wider ion angular distribution in the low-density state. Therefore, it becomes easy to make the thickness of the film 15 formed on the unevenness of the substrate 11 nearly uniform.

For example, as depicted in FIG. 5, the film 15 includes a flat section 15a, a sidewall section 15b, and a bottom section 15c. The flat section 15a is formed on the surface 11a of the substrate 11. The sidewall section 15b is formed on the side surface 13b of the trench 13. The bottom section 15c is formed on the bottom surface 13c of the trench 13. The thicknesses of the sidewall section 15b and bottom section 15c can easily be made close to the thickness of the flat section 15a. Further, changes in the film thicknesses of the sidewall section 15b and bottom section 15c can easily be reduced. It is possible to improve the coverage of the film 15 formed in the trench 13.

Further, the film 15 formed when the plasma density is in the low-density state is different in film quality from the film 15 formed when the plasma density is in the high-density state. For example, a low refractive index film 151 is formed in the low-density state, and a high refractive index film 152 is formed in the high-density state. A layer of the low refractive index film 151 and a layer of the high refractive index film 152 are alternately stacked. Each layer of the low refractive index film 151 has a film thickness in a range of 0.1 to 5 nm. Similarly, each layer of the high refractive index film 152 has a film thickness in the range of 0.1 to 5 nm. The reflection of light can be reduced by stacking the low refractive index film 151 and the high refractive index film 152.

### (Specific Examples of Film Types, Film-Forming Gases, Etc.)

The substrate 11 is, for example, a semiconductor substrate formed by silicon (Si), gallium arsenide (GaAs), gallium nitride (GaN), or the like, or an insulation substrate formed by glass (SiO₂) or the like.

The types (film types) of the film 15 to be formed are, for example, SiO, BSG, PSG, BPSG, FSG, SiC, SiN, SiOC, SiON, SiCN, SiOCN, a-Si, a-C, and a-BN. “a-” means amorphous.

The examples of gas used for film formation (film-forming gases) include, as a Si source, for example, TEOS, SiH₄, tetramethoxysilane (Si(OCH₃)₄), tetrapropoxysilane (Si(OC₃H₇)₄), tetrabutoxysilane (Si(OC₄H₉)₄), trimethoxysilane (SiH(OCH₃)₃), triethoxysilane (TES SiH(OC₂H₅)₃), trimethylsilane (3MS SiH(CH₃)₃), tetramethylsilane (4MS Si(CH₃)₄), dimethylphenylsilane (DMPS SiH(C₆H₅)(CH₃)₂), diethoxymethylsilane ((CH₃)₂Si(OC₂H₅)₂), hexamethylcyclotrisiloxane (HMCTS), tetramethylcyclotetrasiloxane (TMCTS) HSi(CH₃)O)₄), octamethylcyclotetrasiloxane (OMCTS (SiO(CH₃)₂)₄), hexamethyldisilazane (HMDS (CH₃)₃Si—NH—Si(CH₃)₃), hexamethyldisiloxane (HMDSO (CH₃)₃Si—O—Si(CH₃)₃), tetramethyldisiloxane (TMDSO (CH₃)₂HSi—O—SiH(CH₃)₂), hexakisethylaminodisilane (Si₂(NHC₂H₅)₆), trisdimethylaminosilane (3DMAS, SiH(N(CH₃)₂)₃), tetradimethylaminosilane (4DMAS, Si(N(CH₃)₂)₄), bisdiethylaminosilane (((C₂H₅)₂N)₂SiH₂), trisilylamine (TSA (SiH₃)₃N), SiF₄, triethoxyfluorasilane (SiF(OC₂H₅)₃), SiCl₄, SiCl₂H₂, or hexachlorodisilane (Si₂Cl₆). Further, a hydrocarbon source such as CH₄, C₂H₄, C₂H₆, or C₇H₈, an oxidizing agent such as O₂, O₃, N₂O, CO₂, or CO, a nitriding agent such as NH₃ or N₂, or a film-forming gas containing B, P, or F may be added.

In a case where a hydrocarbon source, such as CH₄, C₂H₄, C₂H₆, or C₇H₈, is used for film formation, a nitriding agent, such as NH₃ or N₂, or a film-forming gas containing B, P, or F may be added to such a hydrocarbon source.

It should be noted that the type of film to be formed and the film-forming gas used for film formation are not limited to those described above. The present disclosure is applicable to film types other than those mentioned above, and film-forming gases other than those mentioned above may be used.

Further, the density-modulated plasma is applicable not only to a plasma CVD process, but also to processes such as a plasma-based ion implantation process and a dry etching process. Even in the latter case, the density-modulated plasma provides improved coverage.

### (Film Forming Apparatus)

FIG. 6 is a schematic diagram illustrating an example configuration of a film forming apparatus 50 according to the first embodiment of the present disclosure. As depicted in FIG. 6, the film forming apparatus 50 includes the chamber 51, the anode electrode 52, the cathode electrode 53, an AC power supply 54, a modulation circuit 55, a bias circuit 56, a supply port 57, an exhaust port 58, and a vacuum pump (not depicted). The chamber 51 is capable of maintaining a vacuum state. The anode electrode 52 is disposed in the chamber 51. The cathode electrode 53 is disposed in the chamber 51 and positioned to face the anode electrode 52. The modulation circuit 55 modulates power that is outputted from the AC power supply 54. The bias circuit 56 applies bias power (e.g., DC voltage). The supply port 57 supplies a source gas into the chamber 51. The exhaust port 58 evacuates the chamber 51. The vacuum pump (not depicted) is connected to the exhaust port 58. For example, the modulation circuit 55 modulates power in the RF band (13.56 MHz) to generate input power (see, for example, FIG. 3), and applies the generated input power to the anode electrode 52. The bias circuit 56 applies a negative DC voltage to the cathode electrode 53 as the bias power.

By using RF-band power, the modulation circuit 55 is able to alternately and repeatedly output a low voltage output and a high voltage output at a constant frequency at intervals of 0.5 microseconds to 10 seconds (e.g., at intervals of several milliseconds). For example, as depicted in FIG. 3, the modulation circuit 55 changes the voltage amplitude of the input power at intervals of several milliseconds. Consequently, as depicted in FIG. 2, the density-modulated plasma that repeatedly alternates between the low- and high-density states can be generated in the chamber 51 without significantly changing the gas composition, gas flow rate, or pressure, which are major factors in plasma generation and stabilization.

The film forming apparatus 50 changes the plasma density in the chamber 51 according to the preset waveform (e.g., the waveform depicted in FIG. 2) while forming the film 15 on the substrate 11 disposed in the chamber 51 by using a plasma CVD method.

### Advantageous Effects of First Embodiment

As described above, a semiconductor device manufacturing method according to the first embodiment of the present disclosure includes a film formation process of forming the film 15 on the side toward the surface 11a of the substrate 11 disposed in the chamber 51 by using the plasma CVD method. The film formation process changes the plasma density in the chamber 51 according to the preset waveform (e.g., the waveform depicted in FIG. 2) while forming the film 15.

Accordingly, the plasma density in the chamber repeatedly alternates between the low- and high-density states. The ion angular distribution with respect to the surface 11a of the substrate 11 changes during film formation, and becomes narrower in the high-density state but wider in the low-density state. This makes it easy for the ions to reach the side surface 13b and bottom surface 13c of the trench 13 provided on the surface 11a of the substrate 11. As a result, the film 15 can be formed conformally (e.g., formed along the side surface 13b and bottom surface 13c of the trench 13). This makes it possible to improve coverage.

Further, when film formation is performed by using the density-modulated plasma, the plasma atmosphere remains uninterrupted during film formation. Therefore, the time required for film formation is equivalent to the time required in a case where film formation is performed by ordinary plasma CVD (e.g., the comparative example depicted in FIGS. 11A to 11C). Film formation using the density-modulated plasma does not require combining ordinary plasma CVD with another film formation process (e.g., ALD) or an etching process, and can be completed in a single process, resulting in high productivity.

Further, the size of nanoparticles generated in the gas phase within the chamber tends to become smaller as the plasma density decreases. The smaller the size of the nanoparticles, the higher the density of the film formed by aggregation of the nanoparticles tends to be. In plasma CVD using the density-modulated plasma depicted in FIG. 2, the plasma density decreases at regular intervals. Therefore, the density of the film in the trench can be made higher than in a case where film formation is performed by ordinary plasma CVD. This makes it possible to improve the film quality.

As described above, performing plasma CVD by using the density-modulated plasma makes it possible to form the film 15 with excellent coverage and excellent quality while suppressing a decrease in productivity. Consequently, coverage can be improved while a decrease in productivity can be suppressed. This makes it possible to provide the semiconductor device manufacturing method and the film forming apparatus 50 that are able to improve coverage and film quality while suppressing a decrease in productivity.

It should be noted that semiconductor devices to which the technology of the present disclosure is applicable are various semiconductor devices in which elements are formed on a semiconductor substrate, such as an imaging device, a display device, a logic circuit, and an analog circuit. The imaging device to which the technology of the present disclosure is applicable is, for example, a CMOS (Complementary Metal Oxide Semiconductor) image sensor or an AI (artificial intelligence) sensor having an AI processing function. The display device to which the technology of the present disclosure is applicable is, for example, a liquid crystal display device or an organic EL (Organic Electro Luminescence) display device.

### Second Embodiment

When the semiconductor device manufacturing method according to the second embodiment of the present disclosure is adopted, the waveform of the density-modulated plasma may be designed according to the shape of the base of the substrate 11 (e.g., the shape of the trench 13). This allows coverage and film quality to be controlled. Further, a wider range of coverage and film quality can be controlled by giving a slope to the change in plasma density as a design parameter.

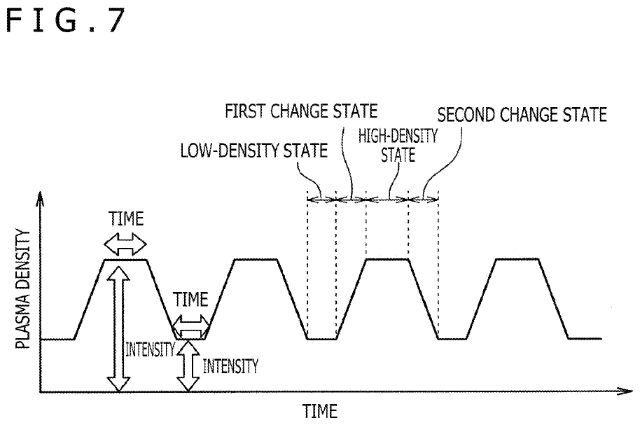

FIG. 7 is a graph illustrating a waveform of the density-modulated plasma according to the second embodiment of the present disclosure. In FIG. 7, the vertical axis represents the plasma density in the chamber of the film forming apparatus, and the horizontal axis represents time. As depicted in FIG. 7, the waveform of the density-modulated plasma according to the second embodiment of the present disclosure is successively placed in the low-density state, a first change state, the high-density state, and a second change state in the order named. In the first change state, the plasma density in the low-density state gradually increases to reach the high-density state. In the second change state, the plasma density in the high-density state gradually decreases to reach the low-density state. The frequency of the waveform of the density-modulated plasma depicted in FIG. 7 is in the range, for example, of 0.1 Hz to 2 MHz.

As is the case with the first embodiment, the second embodiment is configured to be able to generate the density-modulated plasma by modulating the intensity of the input power that is supplied to the anode electrode 52 disposed in the chamber 51 for plasma generation (see FIG. 6).

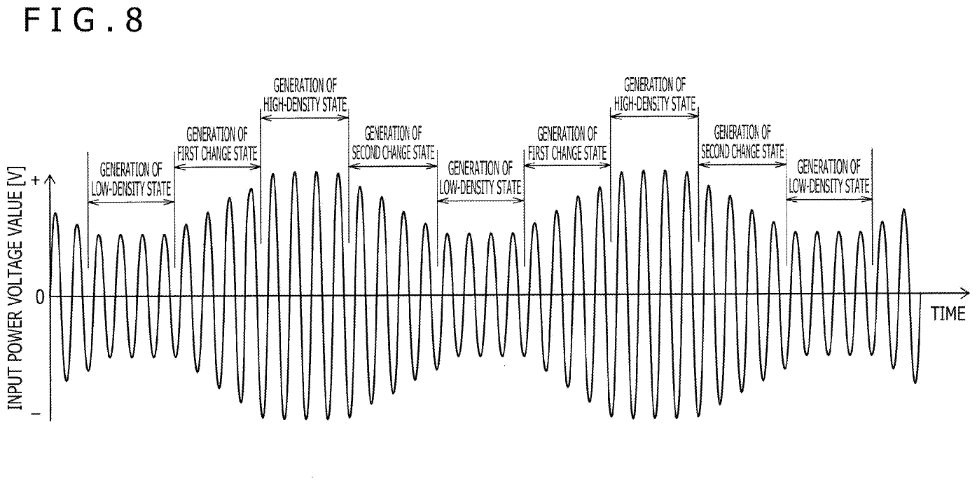

FIG. 8 is a graph illustrating the relation between the voltage amplitude of input power and the generation of high- and low-density states of the density-modulated plasma according to the second embodiment of the present disclosure. In FIG. 8, the vertical axis represents the voltage value of the input power, and the horizontal axis represents time. Regarding FIG. 8, it should be noted that the frequency of the input power is constant, for example, at 13.56 MHz.

In a case where the frequency of the input power is constant, the first change state of the density-modulated plasma can be generated by gradually increasing the voltage amplitude of the input power, and the second change state of the density-modulated plasma can be generated by gradually decreasing the voltage amplitude of the input power. When a period in which the voltage amplitude of the input power is small, a period in which the voltage amplitude gradually increases, a period in which the voltage amplitude is large, and a period in which the voltage amplitude gradually decreases are repeated in the order named, it is possible to generate a waveform with a slope given to the change in plasma density, as depicted in FIG. 7.

As is the case with the first embodiment, the second embodiment is configured such that the intensity of the plasma potential (e.g., equivalent to the level of plasma density in FIG. 7) in each of the low-density state, the first change state, the high-density state, and the second change state of the density-modulated plasma and the time during which each state continues can be adjusted to desired values by controlling the intensity of the input power and the time for maintaining the intensity of the input power.

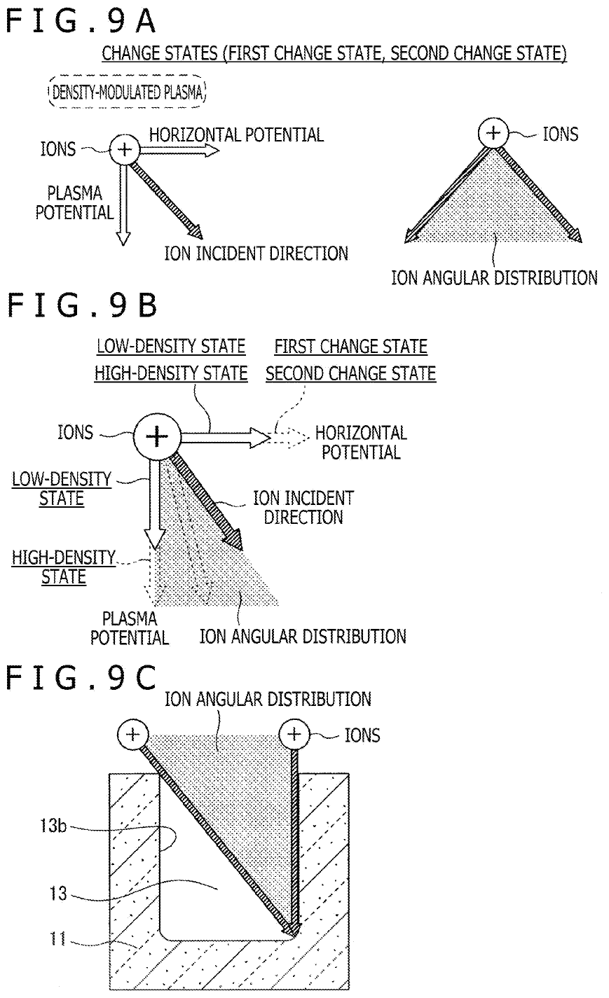

FIG. 9A is a set of diagrams schematically illustrating the plasma potential and horizontal potential acting on the ions and the ion angular distribution in the first change state and second change state of the density-modulated plasma depicted in FIG. 7. In FIG. 9A, the left diagram depicts the plasma potential and the horizontal potential, and the right diagram depicts the ion angular distribution. FIG. 9B is a diagram schematically illustrating the plasma potential and horizontal potential acting on the ions and the ion angular distribution in the low-density state, the first change state, the high-density state, and the second change state of the density-modulated plasma depicted in FIG. 7. FIG. 9C is a cross-sectional view schematically illustrating the incident angle distribution of ions incident on the side surface 13b of the trench 13 that are depicted in FIGS. 9A and 9B.

In the density-modulated plasma depicted in FIG. 7, the slope of the first change state and the slope of the second change state have opposite signs and the same absolute value of magnitude. Therefore, the horizontal electric field generated in the first change state and the horizontal electric field generated in the second change state have opposite directions and the same absolute value of magnitude.

Further, in the density-modulated plasma depicted in FIG. 7, the first change state and the second change state both persist for a fixed period of time. This makes it possible to ensure a long duration of the horizontal potential. The longer the duration of the horizontal potential, the longer the period of time for which the ions are affected by the horizontal potential, and the easier it is for the ions to follow the horizontal potential. Therefore, as depicted in FIGS. 9A and 9B, in the film formation process using the density-modulated plasma according to the second embodiment, the ion angular distribution tends to be wider than in the first embodiment. As depicted in FIG. 9C, the ions are allowed to be incident on the side surface 13b of the trench 13 at a larger angle.

Consequently, the film formation process using the density-modulated plasma depicted in FIG. 7 is able to further improve coverage. Additionally, since the change in plasma density is also continuous, it is possible to provide a gradual change in refractive index between the low refractive index film 151 and the high refractive index film 152, which are depicted in FIG. 5. For example, it is possible to interpose a refractive index change film whose refractive index gradually changes in the stacking direction between the low refractive index film 151 and the high refractive index film 152. It is possible to form a film by successively stacking the films in the order of the low refractive index film 151, a first refractive index change film whose refractive index gradually increases, the high refractive index film 152, and a second refractive index change film whose refractive index gradually decreases.

### Example of Embodiment

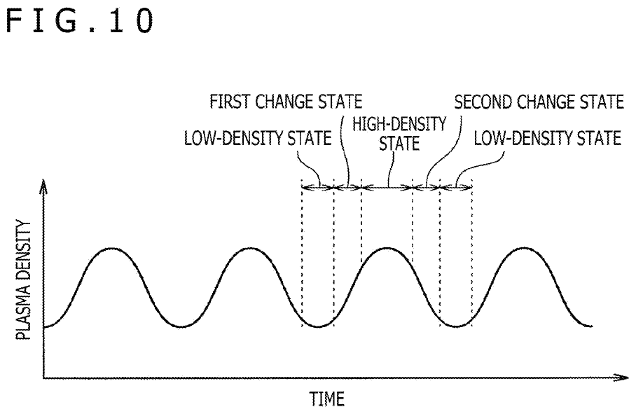

FIG. 10 is a graph illustrating a waveform of the density-modulated plasma according to an example of the second embodiment of the present disclosure. The slope of the waveform of the density-modulated plasma depicted in FIG. 10 constantly changes with time. In each of the low-density state, the first change state, the high-density state, and the second change state, the plasma density is not flat and changes with time.

### Comparative Example

FIG. 11A is a graph illustrating a waveform of plasma according to a comparative example of the present disclosure. As depicted in FIG. 11A, the waveform of the plasma according to the comparative example is flat. The plasma density is constant at a high density value from the beginning to the end of film formation. FIG. 11B is a diagram schematically illustrating the plasma potential and horizontal potential acting on ions and the ion angular distribution in the comparative example depicted in FIG. 11A. In FIG. 11B, the left diagram depicts the plasma potential and the horizontal potential, and the right diagram depicts the ion angular distribution. FIG. 11C is a cross-sectional view schematically illustrating the incident angle distribution of ions incident on the side surface 13b of the trench 13 that are depicted in FIG. 11B.

As depicted in FIGS. 11A and 11, in the comparative example, the plasma density is constant at a high density value, and the horizontal potential is low. Therefore, as depicted in FIG. 11C, the ions are incident nearly perpendicularly on the surface 11a of the substrate 11 (nearly horizontally on the side surface 13b of the trench 13).

### (Results of Evaluation)

### (A) Coverage

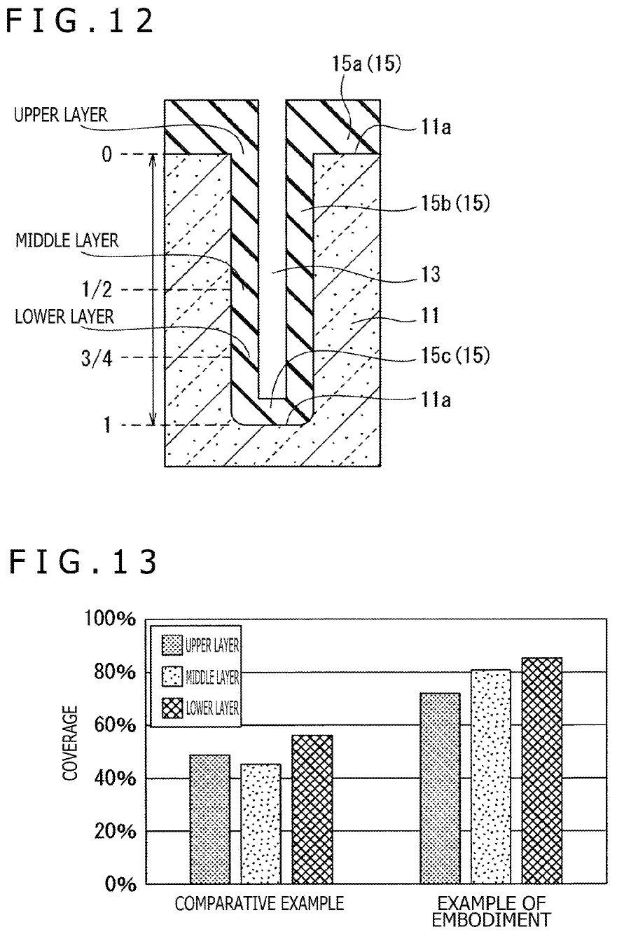

FIG. 12 is a cross-sectional view illustrating evaluation parts of the film 15. As depicted in FIG. 12, the depth from the surface 11a of the substrate 11 to the bottom surface of the trench 13 is assumed to be a depth of 1. A depth of 0 represents the surface 11a of the substrate 11, and a depth of 1 represents the bottom surface of the trench 13. Hereinafter, a part of the trench 13 having a depth of approximately 0 will be referred to as the upper layer, a part of the trench 13 having a depth of approximately ½ will be referred to as the middle layer, and a part of the trench 13 having a depth of approximately ¾ will be referred to as the lower layer.

FIG. 13 is a graph illustrating the results of evaluation of coverage in the example of the second embodiment and in the comparative example. As depicted in FIG. 13, it was confirmed that the film 15 formed by using the density-modulated plasma according to the example of the second embodiment provides better coverage in each of the upper, middle, and lower layers than the film formed by using a constant-density plasma according to the comparative example.

It should be noted that the coverage was calculated by using Equation (1) below. In Equation (1), the “film thickness of the flat section” is the thickness of the flat section 15a of the film 15 that is formed on the surface 11a of the substrate 11.

Coverage [%]=(the film thickness of the thinnest part+the film thickness of the flat section)×100 (1)

As the coverage of each of the upper, middle, and lower layers approaches 100%, the film thickness in the vicinity of each of the upper, middle, and lower layers approaches the film thickness of the flat section 15a.

### (B) Film Quality

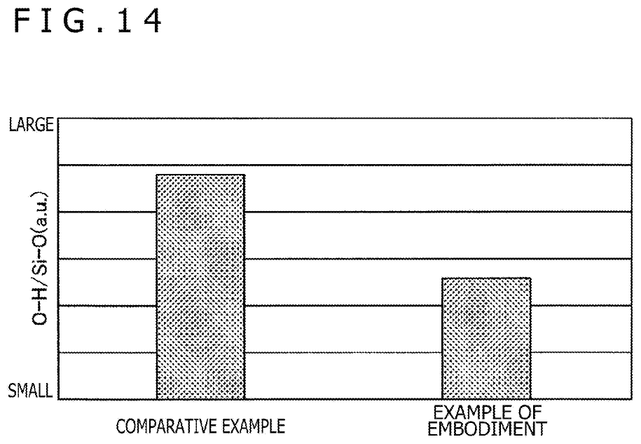

FIG. 14 is a graph illustrating the results of evaluation of film quality in the example of the second embodiment and in the comparative example. For this evaluation, the ratio between O—H and Si—O bonds in film (O—H/Si—O amount) regarding the film 15 formed by using the density-modulated plasma according to the example of the second embodiment and the film formed by the constant-density plasma according to comparative example was measured by FT-IR (Fourier Transform Infrared Spectroscopy). Although not depicted in FIG. 14, in a sample with no unevenness (i.e., the sample having only a flat area), there was no difference in the O—H/Si—O amount between the example of the second embodiment and the comparative example. However, in a sample to which a sidewall section formed on the side surface of the trench and a bottom section formed on the bottom surface of the trench were added in addition to the flat section, the O—H/Si—O amount was smaller in the example of the second embodiment than in the comparative example as depicted in FIG. 14. This indicates that the film quality of the sidewall and bottom sections differs between the example of the second embodiment and the comparative example.

In the comparative example, since the reaction within the trench 13 is insufficient, the sidewall and bottom sections are formed into sparse films that easily absorb moisture from the atmosphere (i.e., absorb a large amount of moisture). Therefore, it is possible that the O—H/Si—O amount measured by FT-IR is large. Meanwhile, in the example of the second embodiment, the sidewall section 15b and the bottom section 15c are formed into dense films by the density-modulated plasma, and thus do not readily absorb the moisture from the atmosphere (i.e., absorb a small amount of moisture). For this reason, it is possible that, in the example of the second embodiment, the O—H/Si—O amount measured by FT-IR is small.

Further, although not depicted in the drawings, in the comparative example, the wet etching rate of the sidewall and bottom sections was equal to or more than three times the etching rate of the flat section. Meanwhile, in the example of the second embodiment, the wet etching rate of the sidewall section 15b and bottom section 15c was equal to or less than two times the etching rate of the flat section 15a.

From the above results, it is confirmed that the density-modulated plasma according to the example of the second embodiment is able to form a denser film (i.e., a film with higher film quality) in the trench 13 than the constant-density plasma according to the comparative example.

### Advantageous Effects of Second Embodiment

As described above, the waveform of the density-modulated plasma according to the second embodiment of the present disclosure is in one of the different states, namely, the low-density state, the first change state, the high-density state, and the second change state. The low-density state is a state in which the plasma density is low. The first change state is a state in which the plasma density gradually increases from the low-density state and reaches the high-density state where the plasma density is high. The second change state is a state in which the plasma density gradually decreases from the high-density state and reaches the low-density state. The state of the waveform of the density-modulated plasma according to the second embodiment of the present disclosure repeatedly changes in an order of the low-density state, the first change state, the high-density state, and the second change state.

Consequently, it is possible to ensure a long duration of the horizontal potential. This allows the ions to easily follow the horizontal potential, and makes it easy for the ion angular distribution to spread more widely. This enables the ions to be incident on the side surface 13b of the trench 13 at a larger angle, making it possible to further improve the coverage.

### Third Embodiment

The first and second embodiments have been described above on the assumption that the voltage amplitude of the input power is modulated to modulate the intensity of the input power and generate the density-modulated plasma in the chamber. However, the embodiments of the present disclosure are not limited to the use of such a plasma density modulation method. In the embodiments of the present disclosure, the plasma density may alternatively be modulated by modulating the frequency of the input power.

For example, the plasma density may be placed in the low-density state by using an input power frequency lower than 13.56 MHz. Further, in this case, the plasma density may be placed in the high-density state by using an input power frequency of 13.56 MHz or higher. The input power frequency is modulated, for example, by the modulation circuit 55 (see FIG. 6) of the film forming apparatus 50. Even when such a method is used, the density-modulated plasma can be generated in the chamber 51, as in the first and second embodiments described above.

Further, the modulation circuit 55 may modulate the plasma density by modulating not only one of the amplitude and frequency of the input power but also both of them. In the case where the amplitude and frequency of the input power are both modulated, the number of plasma density modulation parameters increases. This makes it possible to modulate the plasma density more finely over a wider range.

Moreover, in the embodiments of the present disclosure, the plasma potential acting on the ions may be adjusted by modulating the intensity (e.g., the intensity of DC voltage) of the bias power supplied to the cathode electrode 53. For example, the plasma potential can be increased with respect to the horizontal potential by increasing the bias power, and thus the ion angular distribution can be decreased. The plasma potential can be decreased with respect to the horizontal potential by decreasing the bias power, and thus the ion angular distribution can be increased. Such bias power modulation is performed, for example, by the bias circuit 56 (see FIG. 6) of the film forming apparatus 50. The ion angular distribution can be adjusted more finely over a wider range by combining the modulation of the input power by the modulation circuit 55 with the modulation of the bias power by the bias circuit 56.

### Specific Examples

As regards the waveform of the density-modulated plasma according to the embodiments of the present disclosure, there may be variously modified waveforms in addition to those depicted in FIGS. 2, 7, and 10. Hereinafter, multiple waveforms will be enumerated as specific waveform examples of the present disclosure, including, for example, the waveforms depicted in FIGS. 2, 7, and 10 and modifications thereof.

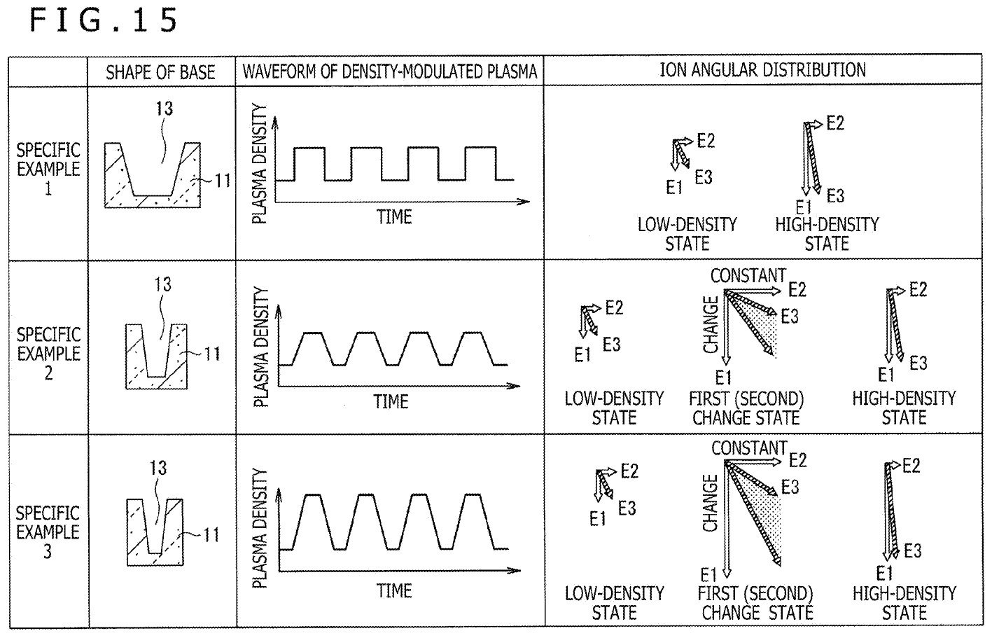

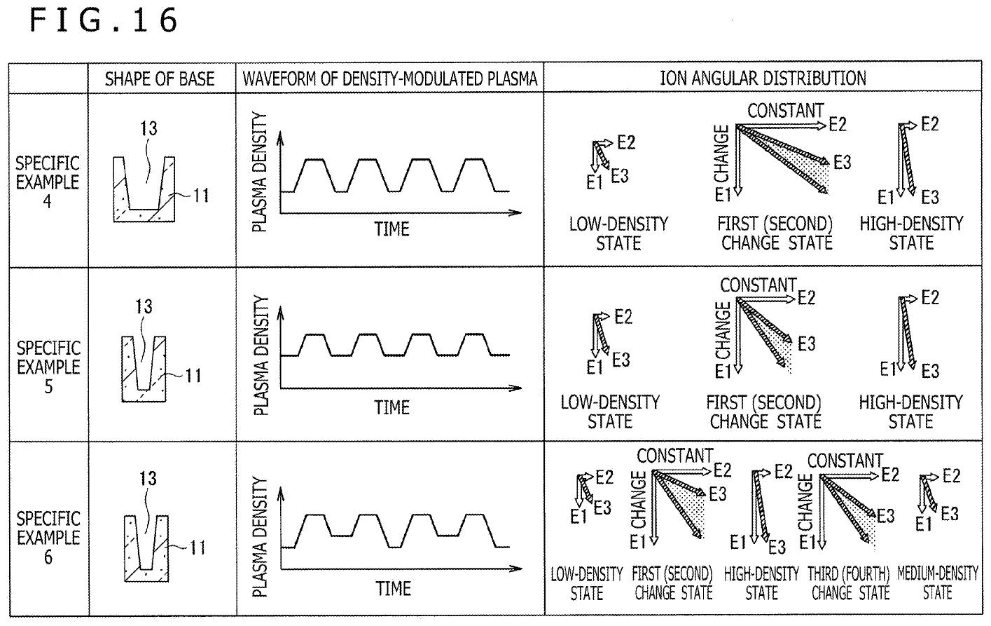

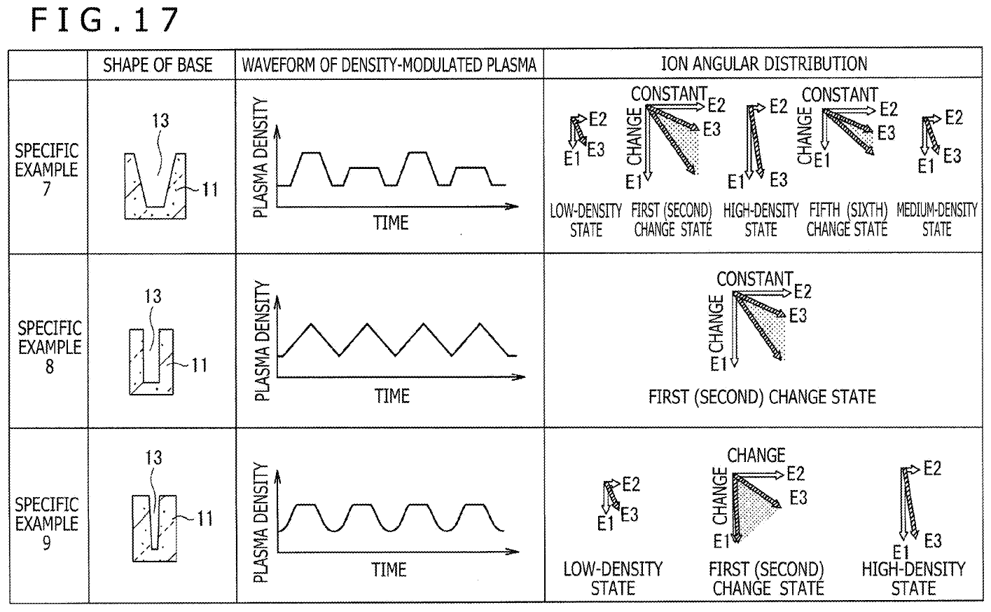

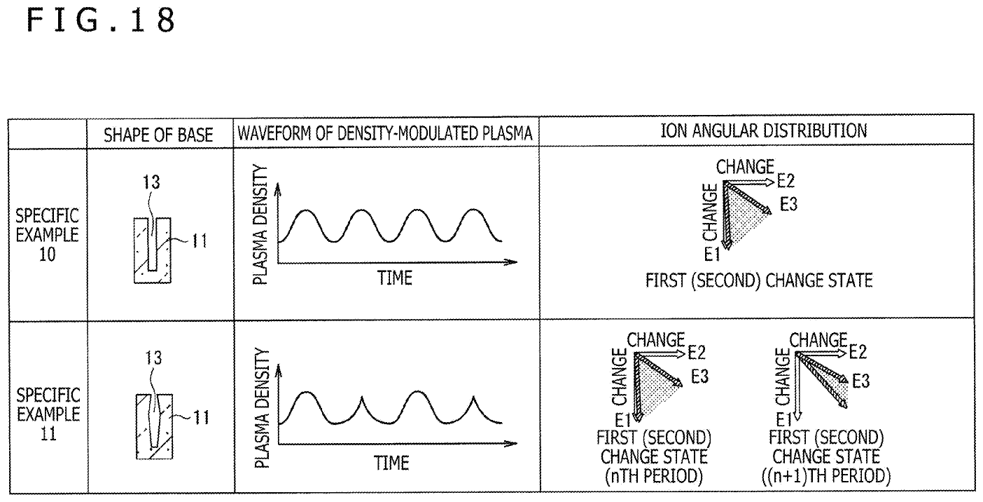

FIG. 15 is a diagram illustrating specific examples 1 to 3 of the density-modulated plasma according to the embodiments of the present disclosure. FIG. 16 is a diagram illustrating specific examples 4 to 6 of the density-modulated plasma according to the embodiments of the present disclosure. FIG. 17 is a diagram illustrating specific examples 7 to 9 of the density-modulated plasma according to the embodiments of the present disclosure. FIG. 18 is a diagram illustrating specific examples 10 and 11 of the density-modulated plasma according to the embodiments of the present disclosure.

In each of specific examples 1 to 11, which are illustrated in FIGS. 15 to 18, the preferred base shape, the waveform of the density-modulated plasma, and the ion angular distribution are depicted in this order from left to right. It should be noted that in each of specific examples 1 to 11, the shape of the trench is depicted as the base shape. In addition, in the column depicting the ion angular distribution, E1 indicates the plasma potential acting on the ions, E2 indicates the horizontal potential acting on the ions, and E3 indicates the direction of the composite electric field that is a combination of the vertical electric field and the horizontal electric field.

Specific example 1 depicts the waveform of the density-modulated plasma (basic waveform 1) that is described with reference to FIG. 2, which relates to the first embodiment of the present disclosure.

Specific example 2 depicts the waveform of the density-modulated plasma (basic waveform 2) that is described with reference to FIG. 7, which relates to the second embodiment of the present disclosure.

Specific example 3 is a modification of specific example 2 and depicts a waveform that is obtained when the plasma density in the high-density state is higher than in specific example 2. In this waveform, the plasma density in the high-density state is high, so that the ions easily reach the bottom of the trench. Therefore, even if the frontage of the trench is narrow, coverage can be improved.

Specific example 4 is a modification of specific example 2 and depicts a waveform that is obtained in a case where the slope of the plasma density in the first and second change states is made greater (e.g., the slope is steeper) than in specific example 2. This waveform results in generating a high horizontal potential, so that the direction of the composite electric field can be shifted to the horizontal direction. This allows the ions to be incident on the side surface of the trench at an adequate angle.

Specific example 5 is a modification of specific example 2 and depicts a waveform that is obtained by reducing the difference in plasma density between the low-density state and the high-density state (that is a modulation width). The slope of the plasma density in the high-density state and the slope of the plasma density in the first and second change states are the same as those in specific example 2. This waveform results in increasing the plasma potential in a low-potential state, and results in decreasing the amount of change in the plasma potential in the first and second change states. Therefore, the direction of the composite electric field can be shifted to the vertical direction.

Specific example 6 is a modification of specific example 2 and depicts a waveform that is obtained in a case where the waveform of the density-modulated plasma is in a medium-density state. The medium-density state is a state in which the plasma density is intermediate between the low-density state and the high-density state. The state of this waveform repeatedly changes in the order of the low-density state, the first change state, the high-density state, a third change state, the medium-density state, a fourth change state, the high-density state, and the second change state. The third change state is a state in which the plasma density changes from the high-density state to the medium-density state. The fourth change state is a state in which the plasma density changes from the medium-density state to the high-density state. The slopes of the plasma density in the first, second, third, and fourth change states have the same absolute value. In this waveform, the low-density state, the medium-density state, the high-density state, the first (second) change state, and the third (fourth) change state differ in the direction of the composite electric field. This allows the ions to be incident on the trench at more diverse angles.

Specific example 7 is a modification of specific example 2 and depicts a waveform that is obtained in a case where the waveform of the density-modulated plasma is in the medium-density state. The state of this waveform repeatedly changes in the order of the low-density state, the first change state, the high-density state, the second change state, the low-density state, a fifth change state, the medium-density state, and a sixth change state. The fifth change state is a state in which the plasma density changes from the low-density state to the medium-density state. The sixth change state is a state in which the plasma density changes from the medium-density state to the low-density state. The slopes of the plasma density in the first, second, fifth, and sixth change states have the same absolute value. In this waveform, the low-density state, the medium-density state, the high-density state, the first (second) change state, and the fifth (sixth) change state differ in the direction of the composite electric field. This allows the ions to be incident on the trench at more diverse angles.

Specific example 8 is a modification of specific example 2 and depicts a waveform that is obtained in a case where the duration of the low-density state and the duration of the high-density state are both short. For example, the duration of the high-density state and the duration of the low-density state may both be zero. In such a case, the resulting waveform repeatedly alternates between the first change state and the second change state and has no flat section in which the plasma density is constant. The slopes of the plasma density in the first and second change states have the same absolute value. In this waveform, the horizontal potential is high and continues for a long period of time. As a result, more ions can be incident on the side surface of the trench at an adequate angle.

Specific example 9 is a modification of specific example 2 and depicts a waveform in which the slopes of the plasma density in the first and second change states change in their own manner. In this waveform, the horizontal potential changes in each of the first and second change states. Therefore, it is possible to provide diversity (variation) in the magnitude and direction of the composite electric field. This allows the ions to be incident on the trench at more diverse angles and with more diverse energies.

Specific example 10 depicts a waveform derived from the example of the second embodiment, which is depicted in FIG. 10, and is also a modification of specific example 8. In this waveform, the slopes of the plasma density in the first and second change states change in their own manner. In this waveform, the horizontal potential changes in each of the first and second change states. Therefore, it is possible to provide diversity in the magnitude and direction of the composite electric field. This allows the ions to be incident on the trench at more diverse angles and with more diverse energies.

Specific example 11 is a modification of specific example 10 and depicts a case where the slope of change in the plasma density differs from one cycle period to another. In the waveform depicted by specific example 11, the slope becomes smaller as the plasma density becomes higher in the waveform of the nth period (n is an integer), and the slope becomes larger as the plasma density becomes higher in the waveform of the (n+1)th period. It is possible to provide greater diversity in the magnitude and direction of the composite electric field.

### Alternative Embodiments

While the present disclosure has been described in conjunction with the embodiments and with the examples and modifications thereof, it is to be understood that the present disclosure is not limited by the statements and drawings, which form part of the present disclosure. Various alternative embodiments, examples thereof, and operational technologies will be apparent to persons skilled in the art from the present disclosure. It goes without saying that the technology provided by the present disclosure includes, for example, various embodiments not described in this document. At least one of various omissions, substitutions, and changes of component elements may be made without departing from the spirit and scope of the above-described embodiments and of the examples and modifications thereof. Further, the advantageous effects described in this document are merely illustrative and not restrictive. The present disclosure can additionally provide advantageous effects other than those described in this document.

Note that the present technology may also be implemented in the following configurations.
(1)
   A semiconductor device manufacturing method including:
   a film formation process of forming a film on a side toward one surface of a substrate disposed in a chamber by using a plasma CVD method,
   in which the film formation process changes plasma density in the chamber according to a preset waveform while forming the film.
(2)
   The semiconductor device manufacturing method according to (1) above,
   in which the film formation process forms the film on unevenness that is provided on the side toward the one surface of the substrate.
(3)
   The semiconductor device manufacturing method according to (1) or (2) above,
   in which the waveform includes
      a low-density state where the plasma density is low, and
      a high-density state where the plasma density is high, and
   the waveform repeatedly alternates between the low-density state and the high-density state.
(4)
   The semiconductor device manufacturing method according to (3) above,
   in which the waveform further includes
      a first change state where the plasma density gradually increases from the low-density state and reaches the high-density state, and
      a second change state where the plasma density gradually decreases from the high-density state and reaches the low-density state, and
   the waveform repeatedly changes in an order of the low-density state, the first change state, the high-density state, and the second change state.
(5)
   The semiconductor device manufacturing method according to (3) or (4) above, in which a cycle of the waveform is in a range of 0.1 Hz to 2 MHz.
(6)
   The semiconductor device manufacturing method according to any one of (3) to (5) above,
   in which the film formation process forms the film including a high refractive index film having a thickness in a range of 0.1 to 5 nm and a low refractive index film having a thickness in the range of 0.1 to 5 nm, and forms the film by alternately stacking the high refractive index film and the low refractive index film.
(7)
   The semiconductor device manufacturing method according to any one of (1) to (6) above,
   in which intensity of input power supplied to a first electrode is modulated in order to change the plasma density, the first electrode being disposed in the chamber and used for plasma generation.
(8)
   The semiconductor device manufacturing method according to any one of (1) to (6) above,
   in which a frequency of the input power supplied to the first electrode is modulated in order to change the plasma density, the first electrode being disposed in the chamber and used for plasma generation.
(9)
   The semiconductor device manufacturing method according to any one of (1) to (8) above,
   in which intensity of bias power supplied to a second electrode is modulated, the second electrode being disposed in the chamber and used for substrate bias.
(10)
   A film forming apparatus, in which
   the film forming apparatus changes plasma density in a chamber according to a preset waveform while forming a film on a substrate disposed in the chamber by using a plasma CVD method.

### REFERENCE SIGNS LIST

11: Substrate
11a: Surface
13: Trench
13b: Side surface
13c: Bottom surface
15: Film
15a: Flat section
15b: Sidewall section
15c: Bottom section
50: Film forming apparatus
51: Chamber
52: Anode electrode
53: Cathode electrode
54: AC power supply
55: Modulation circuit
56: Bias circuit
57: Supply port
58: Exhaust port
151: Low refractive index film
152: High refractive index film

What is claimed is:

1. A semiconductor device manufacturing, method comprising:
a film formation process of forming a film on a side toward one surface of a substrate disposed in a chamber by using a plasma CVD method,
wherein the film formation process changes plasma density in the chamber according to a preset waveform while forming the film.

2. The semiconductor device manufacturing method according to claim 1,
wherein the film formation process forms the film on unevenness that is provided on the side toward the one surface of the substrate.

3. The semiconductor device manufacturing method according to claim 1,
wherein the waveform includes
a low-density state where the plasma density is low, and
a high-density state where the plasma density is high, and
the waveform repeatedly alternates between the low-density state and the high-density state.

4. The semiconductor device manufacturing method according to claim 3,
wherein the waveform further includes
a first change state where the plasma density gradually increases from the low-density state and reaches the high-density state, and
a second change state where the plasma density gradually decreases from the high-density state and reaches the low-density state, and
the waveform repeatedly changes in an order of the low-density state, the first change state, the high-density state, and the second change state.

5. The semiconductor device manufacturing method according to claim 3, wherein a cycle of the waveform is in a range of 0.1 Hz to 2 MHz.

6. The semiconductor device manufacturing method according to claim 3,
wherein the film formation process forms the film including a high refractive index film having a thickness in a range of 0.1 to 5 nm and a low refractive index film having a thickness in the range of 0.1 to 5 nm, and forms the film by alternately stacking the high refractive index film and the low refractive index film.

7. The semiconductor device manufacturing method according to claim 1,
wherein intensity of input power supplied to a first electrode is modulated in order to change the plasma density, the first electrode being disposed in the chamber and used for plasma generation.

8. The semiconductor device manufacturing method according to claim 1,
wherein a frequency of the input power supplied to the first electrode is modulated in order to change the plasma density, the first electrode being disposed in the chamber and used for plasma generation.

9. The semiconductor device manufacturing method according to claim 1,
wherein intensity of bias power supplied to a second electrode is modulated, the second electrode being disposed in the chamber and used for substrate bias.

10. A film forming apparatus, wherein
the film forming apparatus changes plasma density in a chamber according to a preset waveform while forming a film on a substrate disposed in the chamber by using a plasma CVD method.
